(19) United States
(12) Patent Application Publication
(10) Pub. No.: US 2005/0112048 A1
(43) Pub. Date: May 26, 2005

(54) Elongated nano-structures and related devices

(76) Inventors: Loucas Tsakalakos, Niskayuna, NY (US); Ji-Ung Lee, Niskayuna, NY (US); William Hullinger Huber, Scotia, NY (US); Reed Roeder Corderman, Niskayuna, NY (US); Vanita Mani, Clifton, NY (US)

Correspondence Address: ARNALL GOLDEN GREGORY LLP;Suite 2800, 1201 West Peachtree Street, Atlanta, GA, 30309, US

(21) Appl. No.: 10/722,700

(22) Filed: Nov. 25, 2003

(51) Int. Cl. B01J 21/18; B01J 27/20; B01J 27/22; C01B 31/30; C23C 16/00

(52) U.S. Cl. 423/439; 502/177; 502/174; 427/249.1

(57) ABSTRACT

In a method of making an elongated carbide nanostructure, a plurality of spatially-separated catalyst particles is applied to a substrate. The spatially-separated catalyst particles and at least a portion of the substrate are exposed to a metal-containing vapor at a preselected temperature and for a period sufficient to cause an inorganic nano-structure to form between the substrate and at least one of the catalyst particles. The inorganic nano-structure is exposed to a carbon-containing vapor source at a preselected temperature and for a period sufficient to carburize the inorganic nano-structure.

### STATEMENT REGARDING GOVERNMENT RIGHTS

This invention was made with Government support under Contract No. 70NANB2H3030, awarded by the National Institute of Standards and Technology, Department of Commerce, and the United States Government therefore has certain rights in the invention.

### BACKGROUND

1. Field of the Invention

The invention relates to nano-scale structures and, more specifically, to elongated nano-structures.

2. Description of the Prior Art

Field emission devices (gated or ungated) have applications in X-ray imaging, medical imaging systems, displays, electronics, microwave amplifiers, fluorescent lamp cathodes, gas discharge tubes, and many other electrical systems. Other applications for field emission devices include sensors, photonic bandgap devices, and wide bandgap semiconductor devices.

Carbon nanotubes are currently being researched as electron emission sources in, for example, flat panel field emission display (“FED”) applications, microwave power amplifier applications, transistor applications and electron-beam lithography applications. The carbon nanotubes are typically synthesized through an arc discharge method, a chemical vapor deposition (CVD) method or a laser ablation method. Carbon nanotubes offer the advantage of having high aspect ratios which increases the field enhancement factor and therefore the extraction of electrons at relatively low electric fields. Carbon nanotubes, however, exhibit a fairly high work function, and are prone to damage under typical operating conditions, limiting the life and effectiveness of the devices. What is needed therefore is a material more robust and with a lower work function than carbon, but with a cylindrical geometry and diameters in the 10-100 nm range.

Carbide materials may be preferred due to their chemical stability, mechanical hardness and strength, high electrical conductivity, and relatively low work function. These characteristics make them particularly suited to the environment that may be found in a CT system. Such materials may also be important in superconducting nanodevices, opoelectronic nanodevices, and other similar systems.

Currently, the predominating approach to synthesizing carbide nanorods has been to use a carbon nanotube (CNT) as a template on which a reaction is carried out between the CNT and a metal, metal oxide, or metal iodide in vapor form to produce metal carbide nanarods. However, demonstration of CNT conversion in a device structure has not been shown to date, presumably owing to a number of risks associated with such a process, including the large volume changes (about 60% for CNTs that are converted to MO₂C), adhesion to the substrate after conversion, and the ability to maintain alignment.

Therefore, there is a need for a system that does not require carbon nanotubes as template for carbide nanorod conversion

There is also a need for a system that grows elongated carbide nanostructures in situ directly in a gated structure.

There is also a need for a fabrication procedure that allows for seamless integration with gated device structures as well as control of the lateral density of the nanorods so that electric field shielding does not occur.

### SUMMARY OF THE INVENTION

The disadvantages of the prior art are overcome by the present invention, which, in one aspect, is a method of making an elongated carbide nanostructure. A plurality of spatially-separated catalyst particles is applied to a substrate. The spatially-separated catalyst particles and at least a portion of the substrate are exposed to a metal-containing vapor at a preselected temperature and for a period sufficient to cause an inorganic nano-structure to form between the substrate and at least one of the catalyst particles. The inorganic nano-structure is exposed to a carbon-containing vapor source at a preselected temperature and for a period sufficient to carburize the inorganic nano-structure.

In another aspect, the invention is a method of making a field emission device. A dielectric layer is applied to a substrate. A conductive layer is applied to the dielectric layer, opposite the substrate. At least one cavity is formed in the conductive layer and the dielectric layer, thereby exposing the substrate. At least one nanorod is grown in the cavity.

In another aspect, the invention is a field emission device that includes a substrate that has a top side and an opposite bottom side. A dielectric layer is disposed on the top side. A conductive layer is disposed on top of the dielectric layer opposite the substrate. The conductive layer and the dielectric layer define a cavity extending downwardly to the substrate. At least one nanorod is affixed to the substrate and is substantially disposed within the cavity.

In another aspect, the invention is a nanostructure that includes an inorganic substrate having a top side and a bottom side. A conductive buffer layer is disposed adjacent to the top side. A plurality of elongated carburized metal nanostructures extend from the conductive buffer layer.

In another aspect, the invention is a field emission device that includes a substrate. The substrate has a top side and an opposite bottom side. A dielectric layer is disposed on the top side. A conductive layer is disposed on top of the dielectric layer opposite the substrate. The conductive layer and the dielectric layer define a cavity extending downwardly to the substrate. A conductive platform, having a top surface, is disposed on the top side of the substrate within the cavity. At least one nanorod extends upwardly from the top surface of the conductive platform and is substantially disposed within the cavity.

In yet another aspect, the invention is a structure that includes a polycrystalline nanorod. The polycrystalline nanorod is made of a material selected from: molybdenum carbide, molybdenum silicide, molybdenum oxycarbide, and niobium carbide.

These and other aspects of the invention will become apparent from the following description of the preferred embodiments taken in conjunction with the following drawings. As would be obvious to one skilled in the art, many variations and modifications of the invention may be effected without departing from the spirit and scope of the novel concepts of the disclosure.

### BRIEF DESCRIPTION OF THE FIGURES OF THE DRAWINGS

FIG. 1A is a side elevational view showing a structure-growing step employed in one embodiment of the invention.

FIG. 1B is a side elevational view showing a carburizing step subsequent to the step shown in FIG. 1A.

FIG. 1C is a side elevational view showing an etching step subsequent to the step shown in FIG. 1B.

FIG. 1D is a side elevational view showing a carburized nano-structure formed subsequent to the step shown in FIG. 1C.

FIG. 2A is a side elevational view showing a structure-growing step employed in a second embodiment of the invention.

FIG. 2B is a side elevational view showing a carburizing step subsequent to the step shown in FIG. 2A.

FIG. 2C is a side elevational view showing an etching step subsequent to the step shown in FIG. 2B.

FIG. 2D is a side elevational view showing a carburized nano-structure subsequent to the step shown in FIG. 2C.

FIG. 3A a side elevational view showing a step in making a field emitter.

FIG. 3B is a side elevational view showing a step in making a field emitter according to one embodiment of the invention subsequent to the step shown in FIG. 3A.

FIG. 3C is a side elevational view showing a step in making a field emitter according to one embodiment of the invention subsequent to the step shown in FIG. 3B.

FIG. 3D is a side elevational view showing a step in making a field emitter according to one embodiment of the invention subsequent to the step shown in FIG. 3C.

FIG. 3E is a side elevational view showing a step in making a field emitter according to one embodiment of the invention subsequent to the step shown in FIG. 3D.

FIG. 4A is a side elevational view showing an alternate embodiment of making a field emitter.

FIG. 4B is a side elevational view showing a step subsequent to the step shown in FIG. 4A.

FIG. 4C is a side elevational view showing a step subsequent to the step shown in FIG. 4B.

FIG. 4D is a side elevational view showing a step subsequent to the step shown in FIG. 4C.

FIG. 4E is a side elevational view showing a step subsequent to the step shown in FIG. 4D.

FIG. 5A is a micrograph of a nanorod according to one embodiment of the invention.

FIG. 5B is a micrograph of a nanoribbon according to one embodiment of the invention.

FIG. 5C is a micrograph of a polycrystalline nanorod according to one embodiment of the invention.

### DETAILED DESCRIPTION OF THE INVENTION

A preferred embodiment of the invention is now described in detail. Referring to the drawings, like numbers indicate like parts throughout the views. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” Unless otherwise specified herein, the drawings are not necessarily drawn to scale.

Also, as used herein, “nanorod” means an elongated rod-like structure having a narrowest dimension diameter of less than 800 nanometers (nm).

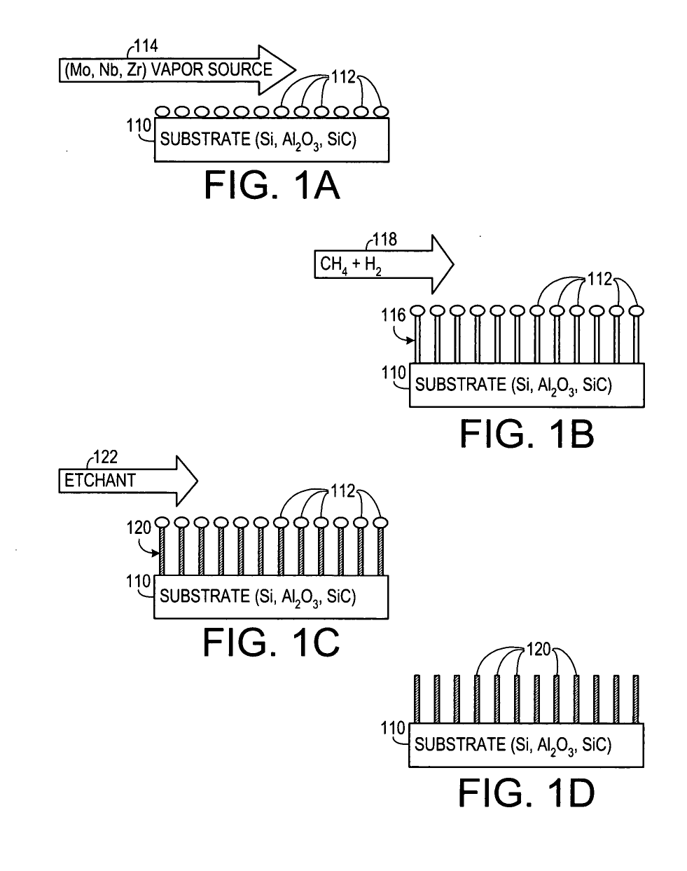

In one embodiment of a method of making elongated nanostructures according to one embodiment of the invention, as shown in FIGS. 1A-1D, a plurality of catalyst particles 112 is deposited on an inorganic substrate 110. The substrate 110 could be made of one of several materials, for example: an oxide, a metal, or an elemental semiconductor. In some embodiments, inorganic monocrystalline substances would be preferable, while in other embodiments a polycrystalline material or an amorphous glass would be preferable. Some specific examples of suitable substrate materials include silicon, sapphire, and silicon carbide.

The catalyst particles 112 could include gold, nickel or cobalt and may be deposited in one of several ways. In one method of applying the catalyst particles 112 to the substrate 110, a thin film of the catalyst is applied to the substrate 110 and is heated to a temperature sufficient to cause the catalyst to enter a liquid phase, thereby causing the catalyst to agglomerate so as to form spatially-separated particles 112. The thin film would typically have a thickness of between 3 nm and 10 nm and could be applied to the substrate 110 by such methods as electron beam evaporation or sputtering. In another example of a way in which the catalyst particles 112 may be applied to the substrate 110, the catalyst particles 112 are deposited within a porous template (such as anodized aluminum oxide or silicon dioxide) to initiate growth. A patterned film of the catalyst may be applied to the substrate 110 so as to control the shape and distribution of the catalyst particles 112.

In yet another example of a way in which the catalyst particles 112 may be applied to the substrate 110, a plurality of nano-particles 112 of the catalyst is suspended in an organic solvent, such as alcohol or acetone and a surfactant to inhibit agglomeration of the nano-particles 112. The nano-particles 112 and the solvent are applied to the substrate 110 and the nano-particles 112 are then dispersed with a spin coater.

The catalyst particles 112 and the substrate 110 are exposed to a metal-containing vapor 114, thereby forming elongated inorganic nanostructures 116 (such as nanorods, nanoribbons and nanobelts) between the substrate 110 and the catalyst particles 112. Examples of metals that may be used in the metal-containing vapor 114 include molybdenum, niobium, hafnium, silicon, tungsten, titanium, zirconium or tantalum.

The inorganic nanostructures 116 are then exposed to a carbon-containing vapor source 118, such as methane, ethylene, ethane, propane, or isopropylene. A reducing gas, such as hydrogen may also be added. This carburizes the inorganic nanostructures 116, thereby making a plurality of elongated carbide nanostructures 120. The nanostructures 120 may be either fully carburized or partially carburized. The elongated carbide nanostructures 120 and the catalyst particles 112 are then etched with an etchant 122 to remove the catalyst particles 112.

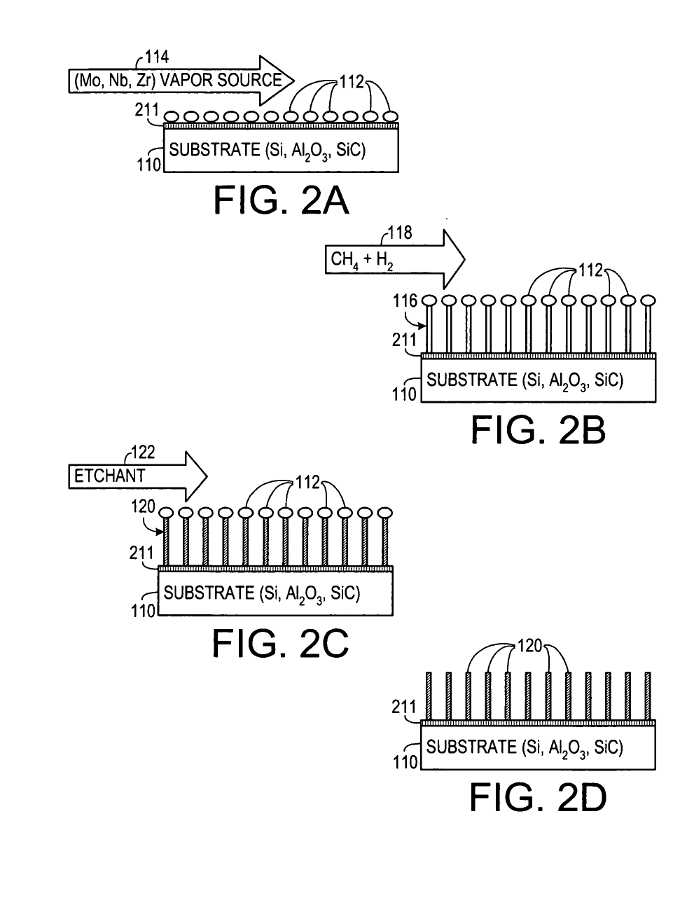

An electrically conductive buffer layer 211, as shown in FIGS. 2A-2D, may be applied to the substrate 110 prior to the step of applying a plurality of spatially-separated catalyst particles 112 to the substrate 110. The buffer layer 211 acts as a diffusion barrier and inhibits the formation of unwanted structures, such as silicides, due to interaction between the reactants and the substrate 110. The buffer layer 211 could include, for example, germanium carbide or silicon carbide applied in an epitaxial process, or a polycrystalline diffusion barrier such as W or Ti—W. In some cases the buffer layer 211 should be suitable to support epitaxial growth of the nanostructure materials of interest. In other cases, epitaxy may not be necessary.

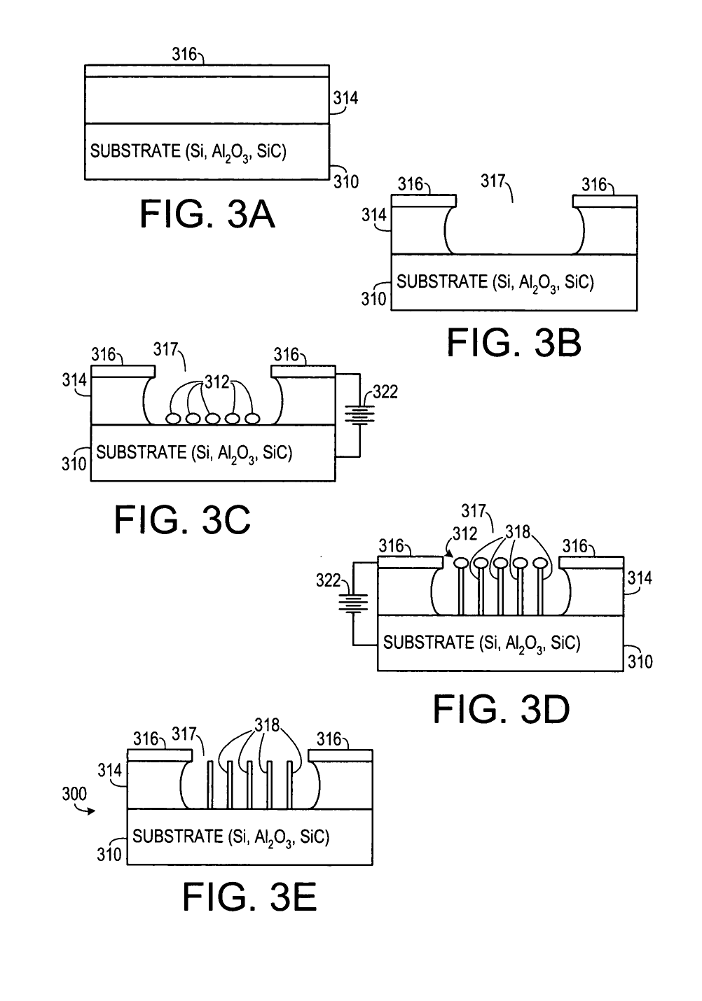

A field emission device 300, according to one embodiment of the invention, is shown in FIGS. 3A-3E. Such a device could be employed with one of many devices, including, for example, an imaging system and a lighting system. The field emission device 300 is made by applying a dielectric layer 314 to the substrate 310 and then a conductive layer 316 to the dielectric layer 314. The dielectric layer 314 typically includes a material such as silicon dioxide, silicon nitride, silicon oxynitride, or aluminum oxide. A cavity 317 is formed in the conductive layer 316 and the dielectric layer 314. Catalyst particles 312 are placed on the substrate 310 in the cavity 317 and nanorods 318 are grown and carburized within the cavity 317, according to the methods described above with reference to FIGS. 1A-1D. The nanorods 318 are typically made from a material such as a carbide, an oxide, a nitride, or an oxycarbide or a silicide. As disclosed above, a patterned catalyst film may be applied within the device cavity. The patterning could be done by photolithography, imprint lithography, e-beam lithography, chemical lithography, or any other method of patterning a thin film.

An electrical field, from a field source 322 may be applied to the catalyst particles 112 and the substrate 110 while they are exposed to the metal-containing vapor 114 to influence the direction of growth of the inorganic nano-structures 116.

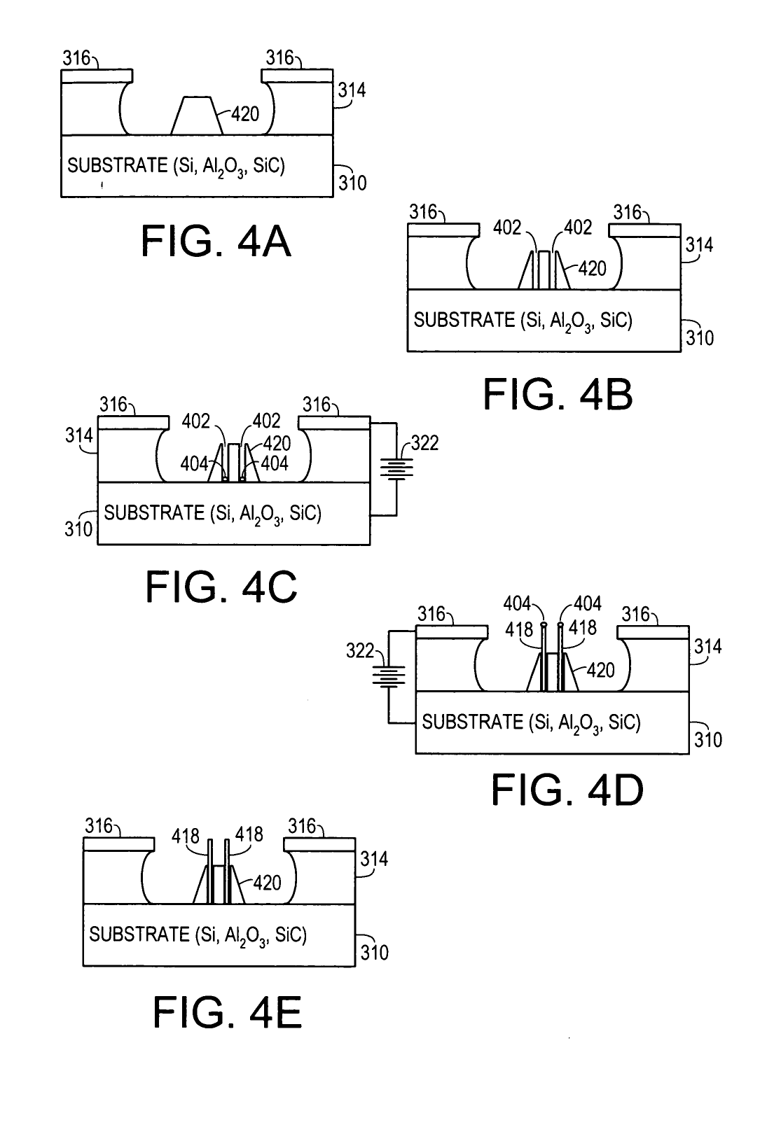

In another embodiment, a conductive platform 420, as shown in FIG. 4, may be disposed on the substrate 310 within a cavity formed in the dielectric layer 314. At least one channel 402 is formed in the conductive platform 420 and a catalyst particle 404 is placed within the channel 402. Nanorods 418 are then grown so as to extend from the top surface of the conductive platform 420. The conductive platform 420 may be made of a material such as silicon or molybdenum. In one embodiment, the conductive platform 420 is a conic-shaped member having a relatively large bottom surface opposite the top surface. In one illustrative embodiment, the material of the conductive platform 420 is applied using an evaporation process while the substrate 310 is held at an angle and is rotated, thereby forming a conic shape. If a voltage source (not shown) is applied to the substrate 310 and the conductive layer 316, then the nanorods 418 will emit electrons. Alternately, rather than forming a channel 402 in the conductive platform 420, the nanorods 418 may be grown from the top surface of the conductive platform 420. In one embodiment the material for the platform 420, as noted above, is aluminum oxide (alumina), but it could also be an insulating metal oxide that can be anodized to form nanopores.

In another embodiment, an aluminum metal support is deposited. The aluminum metal support is subsequently anodized to become a nano-porous aluminum oxide. Catalyst is placed within the pore bottoms and then nanorods are grown. The nano-porous anodized aluminum oxide (AAO) acts a template so that vertically aligned nanostructures are formed. The catalyst film may be put down first followed by the aluminum deposition. Alternately, there are several ways to ensure that catalyst is not plated on the surface within the cavity surrounding the AAO support. These include: (a) Reflow the photoresist so that it covers the Si surface adjacent to the aluminum support, then anodize; (b) Deposit a silicon nitride layer down prior to SiO₂ layer, then dry etch a hole into the nitride so Si is exposed, then deposit aluminum, then electroplate Au. It will not deposit on the silicon. nitride because there is not electrical contact; (c) Place a sacrificial oxide layer on top of the nitride so that any material that deposits there during nanowire growth may be sacrificially removed by wet etching. In this case the trench would be etched by a dry etching method so it is directional and stops just above the nitride in the oxide layer; (d) Use approach (b) but first deposit a gold film so that electroplating is not necessary.

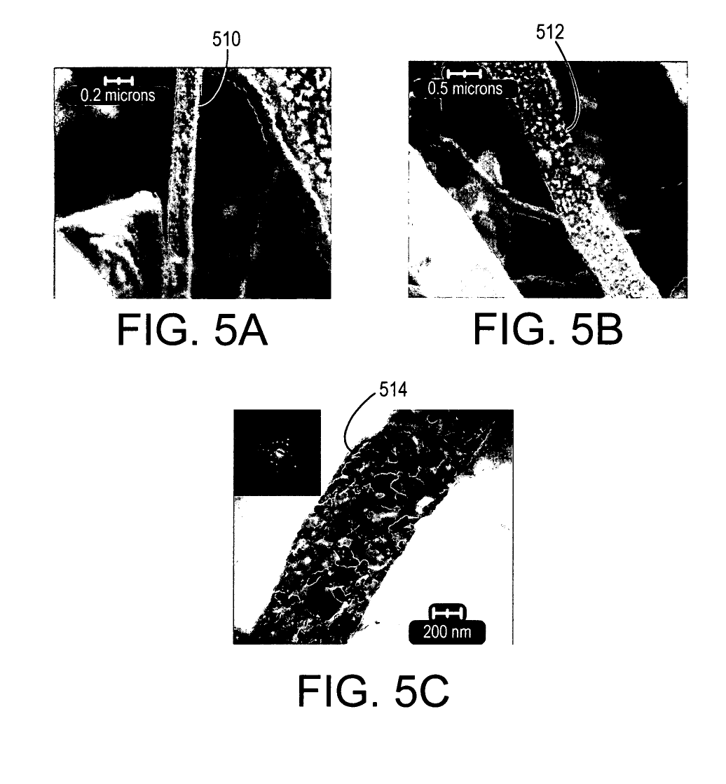

A micrograph of a nanorod 510 made according to one embodiment of the invention is shown in FIG. 5A, a micrograph of a nanobelt 512 made according to one embodiment of the invention is shown in FIG. 5B, and a micrograph of a polycrystalline nanorod 514 made according to one embodiment of the invention is shown in FIG. 5C. The polycrystalline nanorod 514 could be made from a material such as, for example, molybdenum carbide, molybdenum silicide, or niobium carbide. As can be seen from the micrographs shown in FIGS. 5A-5C, nanostructures made according to the methods described above typically have a smaller dimension of less than 800 nm.

One initial proof of concept experiment was carried out with a Mo₂C system. MoO₃ powder was placed in a tube furnace and a silicon wafer coated with a 10 nm Au film was placed downstream (about 1-5 cm) away on a (111)-oriented silicon wafer.

The system was heated to 900° C. Hydrogen and argon were applied at a flow rate of 300 standard cubic centimeters per minute (sccm) H₂/1000 sccm Ar for 5 min and CH₄ in a concentration of 300/1000 sccm for 10 minutes. Similar recipes at 850° C. and 950° C. have also been attempted, and one run on sapphire with a similar catalyst has been tried. The results were that a mixture nanorods and nanoribbons were found on the substrate, which were determined by transmission electron microscopy (TEM) to be nanocrystalline in nature. In one such experiment, field emission with low turn on field (˜1.25 V/um) and high current (up to 300 μA) was measured.

One embodiment of the invention includes a method for synthesis of carbide nanorods and related nanostructures by synthesis of metal oxide nanorods via the vapor-liquid-solid (VLS) mechanism, or a solid state nanowire growth mechanism, followed by in situ reduction and subsequent carburization. These nanostructures may find utility in gated field emission devices. In one embodiment, growth occurred below the eutectic temperature for VLS to take place (e.g., about 1053 C for the Mo—Au system) so growth took place in the solid state.

In one embodiment of the invention is to synthesize oxide nanorods and ribbons using the Vapor-Liquid-Solid (VLS) or related mechanisms for nanostructure growth (e.g., solid state growth mechanisms). In the VLS technique metal vapor that will be part of the composition of the carbide material is fed to appropriate nano-catalyst particles on the substrate surface such that the metal is dissolved and the catalysts become supersaturated. The metal then precipitates as a nanorod and presumably reacts with a CO or residual oxygen to form an oxide nanorod. The oxide nanorods are reduced and/or carburized in situ immediately after growth. If one can control the position of catalyst islands by a secondary means, such as a block copolymer templates or electron beam lithography, then the lateral density of nanorods can be controlled. Alternatively, if a mixed phase is formed, then it may be possible to preferentially etch out one phase such that the density of rods is again diminished controllably. Low nanorod density is desirable to minimize electric field shielding when nanorods are too close together. This process can be carried out within a gated or ungated field emission or other device structure.

The choice of substrate is important. Potential substrates include, for example, silicon, sapphire, and silicon carbide. Silicon will react with the catalyst particles and the metal vapor to form a silicide which, in some cases, may be undesirable. This issue may be overcome by use of a suitable buffer layer. The desirable features of the buffer layer are that it should have the proper epitaxial relationship with the substrate and carbide nanorod (intermediate lattice mismatch with low strain), be a sufficient diffusion barrier for silicon or other elements, have an intermediate thermal expansion coefficient, and be electrically conducting. This last feature is important if a buffer layer is to be used on a semiconducting or insulating substrate. An example of such a buffer layer material is GeC or SiC. However, in some cases it may not be necessary to use an epitaxial buffer layer, in which case a simple diffusion barrier such as a tungsten thin film or Ti—W thin film may be sufficient. It may also be necessary to grow the rods at an appropriate temperature and then carburize at a higher (or lower) temperature. After processing, the metal nanocatalyst may be preferentially etched from the tip of the nanorods and ribbons using an appropriate etchant. It is also possible to grow the metal/oxide nanorods via an oxide-assisted growth mechanism, which does not require a catalyst, or an auto-catalytic process, and then carburize the nanorods. Other structures, such as nano-platelets may also be grown.

In another embodiment, nanorods could be included in a diode structure. Such a diode structure includes a substrate with the nanorods on it, with an anode on the opposite side of the substrate. An electric potential is directly applied between the substrate, which acts as a cathode and a spaced-apart anode plate, with no intermediate gate structure. The processing of this embodiment may be less expensive than other methods and the resulting electric field may be sufficient for applications such as fluorescent lighting.

The above described embodiments are given as illustrative examples only. It will be readily appreciated that many deviations may be made from the specific embodiments disclosed in this specification without departing from the invention. Accordingly, the scope of the invention is to be determined by the claims below rather than being limited to the specifically described embodiments above.

1. A method of making an elongated carbide nanostructure, comprising the steps of:
a. applying a plurality of spatially-separated catalyst particles to a substrate;
b. exposing the spatially-separated catalyst particles and at least a portion of the substrate to a metal-containing vapor at a preselected temperature and for a period sufficient to cause an inorganic nano-structure, including the metal, to form between the substrate and at least one of the catalyst particles; and
c. exposing the inorganic nano-structure to a carbon-containing vapor source at a preselected temperature and for a period sufficient to carburize the inorganic nano-structure, thereby creating an elongated carbide nanostructure.

2. The method of claim 1, further comprising the step of removing a plurality of catalyst particles from the elongated carbide nano-structure.

3. The method of claim 2, wherein the removing step employs etching.

4. The method of claim 1, wherein the inorganic substrate includes a material selected from a group comprising: an oxide; a metal; or an elemental semiconductor, and combinations thereof.

5. The method of claim 1, wherein the carbon-containing vapor source is a gas selected from a group comprising: methane, ethylene ethane, propane, and isopropylene, and combinations thereof.

6. The method of claim 1, wherein the inorganic nano-structure is also exposed to hydrogen gas while being exposed to the carbon-containing vapor source.

7. The method of claim 1, wherein the step of applying a plurality of spatially-separated catalyst particles comprises the steps of:
a. applying a thin film of the catalyst to the substrate; and
b. heating the thin film to a temperature sufficient to cause the catalyst to enter a liquid phase, thereby causing the catalyst to agglomerate so as to form spatially-separated particles.

8. The method of claim 7, wherein the thin film has a thickness of between 3 nm and 10 nm.

9. The method of claim 7, wherein the thin film is applied to the substrate by electron beam evaporation.

10. The method of claim 7, wherein the thin film is applied to the substrate by sputtering.

11. The method of claim 1, further comprising the step of flowing a reducing gas during the carburization process.

12. The method of claim 11, wherein the reducing gas comprises hydrogen.

13. The method of claim 1, wherein the step of applying a plurality of spatially-separated catalyst particles comprises the step of depositing the catalyst particles within a porous template.

14. The method of claim 13, wherein the porous template comprises anodized aluminum oxide.

15. The method of claim 13, wherein the porous template comprises silicon dioxide.

16. The method of claim 1, wherein the step of applying a plurality of spatially-separated catalyst particles comprises the steps of:
a. suspending a plurality of nano-particles of the catalyst in an organic solvent;
b. applying nano-particles and the solvent to the substrate; and
c. dispersing the nano-particles with a spin coater.

17. The method of claim 16, further comprising the step of adding a surfactant to the organic solvent and the nano-particles so as to inhibit agglomeration of the nano-particles.

18. The method of claim 16, wherein the solvent comprises alcohol.

19. The method of claim 16, wherein the solvent comprises acetone.

20. The method of claim 1, wherein the catalyst is selected from a group comprising: gold, nickel, iron, cobalt or gallium, and combinations thereof.

21. The method of claim 1, further comprising the step of applying an electrically conductive buffer layer to the substrate prior to the step of applying a plurality of spatially-separated catalyst particles to the substrate, wherein the buffer layer acts as a diffusion barrier.

22. The method of claim 21, wherein the buffer layer is a material selected from a group comprising: germanium carbide tungsten, silicon carbide or titanium tungsten, and combinations thereof.

23. The method of claim 21, wherein the step of applying an electrically conductive buffer layer employs an epitaxial process.

24. The method of claim 1, further comprising the step of applying an electrical field to the spatially-separated catalyst particles and at least a portion of the substrate while exposed to the metal-containing vapor, thereby influencing direction of growth of the inorganic nano-structure.

25. A method of making a field emission device, comprising the steps of:
a. applying a dielectric layer to a substrate;
b. applying a conductive layer to the dielectric layer, opposite the substrate;
c. forming at least one cavity in the conductive layer and the dielectric layer, thereby exposing the substrate; and
d. growing at least one nanorod in the cavity.

26. The method of claim 25, wherein the step of growing at least one nanorod comprises:
a. applying at least one catalyst particle within the cavity;
b. exposing the catalyst particle and at least a portion of the substrate to a metal vapor and an oxidizing gas at a preselected temperature and for a period sufficient to cause an oxide nanorod, including an oxide of the metal, to form between the substrate and the catalyst particle;
c. exposing the oxide nanorod to a carbon-containing vapor source at a preselected temperature and for a period sufficient to carburize the oxide nanorod; and
d. removing the catalyst particle.

27. The method of claim 26, wherein the step of applying at least one catalyst particle includes the step of applying a patterned catalyst film within the device cavity.

28. The method of claim 26, wherein the removing step is performed by etching.

29. The method of claim 25, further comprising the step of forming a conductive platform on the substrate and within the cavity, wherein the step of growing at least one nanorod in the cavity comprises growing the nanorod from the conductive platform.

30. A field emission device, comprising
a. a substrate having a top side and an opposite bottom side;
b. a dielectric layer disposed on the top side;
c. a conductive layer disposed on top of the dielectric layer opposite the substrate, the conductive layer and the dielectric layer defining a cavity extending downwardly to the substrate; and
d. at least one nanorod affixed to the substrate and substantially disposed within the cavity.

31. The field emission device of claim 30, further comprising a buffer layer affixed to the top side of the substrate.

32. The field emission device of claim 30, employed in an imaging system.

33. The field emission device of claim 30, employed in a lighting system.

34. The field emission device of claim 30, wherein the nanorod is an X-nanorod, wherein X is a material selected from a group comprising: a carbide, an oxide, a nitride, an oxynitride, an oxycarbide or a silicide, and combinations thereof.

35. The field emission device of claim 30, wherein the substrate comprises an inorganic monocrystalline substance.

36. The field emission device of claim 35, wherein the inorganic monocrystalline substance comprises a material selected from a group comprising: silicon, an aluminum oxide, and silicon carbide, and combinations thereof.

37. The field emission device of claim 30, wherein the dielectric layer comprises a material selected from a group comprising: silicon dioxide, silicon nitride, silicon oxynitride, and aluminum oxide, and combinations thereof.

38. A nanostructure, comprising:
a. an inorganic substrate having a top side and a bottom side;
b. a conductive buffer layer disposed adjacent to the top side; and
c. a plurality of elongated carburized metal nanostructures extending from the conductive buffer layer.

39. The nanostructure of claim 38, wherein the inorganic substrate comprises is a crystalline substance, selected from a group consisting of: silicon, aluminum oxide, and silicon carbide, and combinations thereof.

40. The nanostructure of claim 38, wherein the plurality of elongated carburized metal nanostructures comprises at least one nanorod.

41. The nanostructure of claim 38, wherein the plurality of elongated carburized metal nanostructures comprises at least one nanoribbon.

42. The nanostructure of claim 38, wherein the plurality of elongated carburized metal nanostructures each has a smaller dimension of less than 800 nm.

43. The nanostructure of claim 38, wherein the carburized metal is carburized from an oxide of a metal selected from a group comprising: molybdenum, niobium, hafnium, silicon, tungsten, titanium, or zirconium, and combinations thereof.

44. A field emission device, comprising
a. a substrate having a top side and an opposite bottom side;
b. a dielectric layer disposed on the top side;
c. a conductive layer disposed on top of the dielectric layer opposite the substrate, the conductive layer and the dielectric layer defining a cavity extending downwardly to the substrate;
d. a conductive platform, having a top surface, disposed on the top side of the substrate within the cavity; and
e. at least one nanorod affixed to the top surface of the conductive platform and substantially disposed within the cavity.

45. The field emission device of claim 44, wherein the conductive platform comprises a conic-shaped member having a relatively large bottom surface opposite the top surface, the bottom surface affixed to the substrate.

46. The field emission device of claim 44, wherein the conductive platform comprises a material selected from a group comprising: silicon, molybdenum, platinum, palladium, tantalum, or niobium, and combinations thereof.

47. The field emission device of claim 44, wherein the nanorod is a carbide nanorod.

48. The field emission device of claim 44, wherein the substrate comprises an inorganic monocrystalline substance.

49. The field emission device of claim 48, wherein the inorganic monocrystalline substance is selected from a group comprising: silicon, aluminum oxide and silicon carbide, and combinations thereof.

50. The field emission device of claim 44, wherein the substrate comprises a polycrystalline material.

51. The field emission device of claim 44, wherein the substrate comprises amorphous glass.

52. The field emission device of claim 44, wherein the dielectric layer comprises silicon dioxide.

53. A structure including a polycrystalline nanorod comprising a material selected from the group comprising: molybdenum carbide, molybdenum silicide, molybdenum oxycarbide, or niobium carbide.
